(19) United States
(12) Patent Application Publication
(10) Pub. No.: US 2023/0358621 A1
(43) Pub. Date: Nov. 9, 2023

(54) TOUCH AND COLLISION TRANSDUCER SENSOR SIMULATION USING MATRIX LOOKUP TABLE AND SIGNAL GENERATION

(71) Applicant: GM Cruise Holdings LLC, San Francisco, CA (US)

(72) Inventors: Amanda Lind, Brooklyn, NY (US); Amin Aghaei, Fremont, CA (US); Jin Hao, Redondo Beach, CA (US); Jason Edward Foat, San Diego, CA (US)

(73) Assignee: GM Cruise Holdings LLC, San Francisco, CA (US)

(21) Appl. No.: 17/735,661

(22) Filed: May 3, 2022

(51) Int. Cl. G01L 1/16; G06F 30/20; G01P 15/08

(52) U.S. Cl. CPC G01L 1/16; G06F 30/20; G01P 15/08

(57) ABSTRACT

A combination of lookup tables for waveforms and several scaling and delay factors to accurately simulate touch and collision transducer sensor output without the complexity of solving the classical wave equation or performing convolutions in the frequency domain. TACT, as used herein, is a touch and collision transducer sensor used for detecting collisions. When the vehicle collides with an object a wave will be generated by the touch and collision transducer sensors. The waveform can take many forms depending on various parameter. Pre-recorded waveforms can be used to simulate the collisions and produce appropriate outputs. However, the present disclosure contemplates more complex, diverse waveforms which can be produced based on the existing pre-recorded libraries. To this end, simulated waveforms can be produced by scaling, filtering, delaying and combining with road noise, based on the impact material and contact area, at least in part.

### CROSS-REFERENCE TO RELATED APPLICATION

This Application is related to U.S. application Ser. No. 17/095,835 filed Nov. 12, 2020, entitled “Transducer-based Structural Health Monitoring of Autonomous Vehicles” and U.S. application Ser. No. 17/114,167 filed Dec. 7, 2020, entitled “VEHICLE SURFACE IMPACT DETECTION” both of which are hereby incorporated herein in their entirety.

### FIELD OF THE DISCLOSURE

The present disclosure relates generally to the calibration of acoustic systems used in environment sensing. More specifically, the present disclosure pertains to the calibration of spatial sensing and acquisition found in autonomous vehicles.

### BACKGROUND

An autonomous vehicle (AV) is a vehicle that is configured to navigate roadways based upon sensor signals output by sensors of the AV, wherein the autonomous vehicle navigates the roadways without input from a human. The autonomous vehicle is configured to identify and track objects (such as vehicles, pedestrians, bicyclists, static objects, and so forth) based upon the sensor signals output by the sensors of the autonomous vehicle and perform driving maneuvers (such as accelerating, decelerating, turning, stopping, etc.) based upon the identified and tracked objects.

The use of automation in the driving of road vehicles, such as, cars, trucks, and others, has increased as a result of advances in sensing technologies (e.g., object detection and location tracking), control algorithms, and data infrastructures. By combining various enabling technologies like adaptive cruise control (ACC), lane keeping assistance (LKA), electronic power assist steering (EPAS), adaptive front steering, parking assistance, antilock braking (ABS), traction control, electronic stability control (ESC), blind spot detection, GPS and map databases, vehicle to vehicle communication, and other, it becomes possible to operate a vehicle autonomously (i.e., with little or no intervention by a driver).

In the field of autonomous or quasi-autonomous operation of vehicles such as aircrafts, watercrafts or land vehicles, in particular automobiles, which may be manned or unmanned, sensing the surrounding of the vehicle as well as tracking objects in the surrounding of the vehicle may be considered to be crucial for sophisticated functionalities. These functionalities may range from driver assistance systems in different stages of autonomy up to full autonomous driving of the vehicle.

In certain environments, a plurality of different types of sensors for sensing the surrounding of a vehicle are used, such as monoscopic or stereoscopic cameras, light detection and ranging (LiDAR) sensors, and radio detection and ranging (radar) sensors. The different sensor types comprise different characteristics that may be utilized for different tasks.

Features and advantages of the present invention will be presented in the description which follows, and in part will become apparent from the description and the accompanying drawings or may be learned by practice of the invention according to the teachings provided in the description. Objects as well as other features and advantages of the present invention will be realized and attained by an impact simulator particularly pointed out in the Specification in such full, clear, concise, and exact terms as to enable a person having ordinary skill in the art to practice the invention.

This overview is intended to provide an overview of subject matter of the present patent application. It is not intended to provide an exclusive or exhaustive explanation of the invention. Further limitations and disadvantages of conventional and traditional approaches will become apparent to one of skill in the art, through comparison of such systems with some aspects of the present invention as set forth in the remainder of the present application with reference to the drawings.

### SUMMARY

A combination of lookup tables for waveforms and several scaling and delay factors to accurately simulate touch and collision transducer sensor output without the complexity of solving the classical wave equation performing convolutions in the frequency domain is disclosed. TACT, as used herein, is a touch and collision transducer sensor used for detecting collisions. When the vehicle collides with an object a wave will be generated by the touch and collision transducer sensors. The waveform can take many forms depending on various parameter. Pre-recorded waveforms can be used to simulate the collisions and produce appropriate outputs. However, the present disclosure contemplates more complex, diverse waveforms which can be produced based on the existing pre-recorded libraries. To this end, simulated waveforms can be produced by scaling, filtering, delaying and combining with road noise, based on the impact material and contact area, at least in part.

According to one aspect of the present disclosure, a method for simulating a sensor signal which has measured a collision with an object comprises retrieving a waveform from a lookup table, scaling the waveform by a first scaling factor, retrieving a predetermined road noise waveform, and combining the road noise waveform with the waveform scaled by the first scaling factor.

According to one or more aspects of the present disclosure, the waveform is based at least on a material of the object.

According to one or more aspects of the present disclosure, the waveform is based at least on a contact area of the object.

According to one or more aspects of the present disclosure, the first scaling factor is based at least on an inertia of the object.

According to one or more aspects of the present disclosure, the first scaling factor is based at least on an angle of incidence of the object.

According to one or more aspects of the present disclosure, the method further comprises scaling the waveform by a second scaling factor.

According to one or more aspects of the present disclosure, the second scaling factor is based at least on geometric spreading between the object collision and sensor.

According to one or more aspects of the present disclosure, the second scaling factor is based at least on acoustic attenuation between the object collision and sensor.

According to one or more aspects of the present disclosure, wherein the second scaling factor is a transfer function.

According to one or more aspects of the present disclosure, the transfer function is in the frequency domain.

According to one or more aspects of the present disclosure, the method further comprises introducing a temporal delay in the scaled waveform.

According to one or more aspects of the present disclosure, the temporal delay is based at least on a distance between the object collision and sensor.

According to one or more aspects of the present disclosure, the road noise waveform based on at least one of a vehicle's speed and road quality.

According to one aspect of the present disclosure, a system for method further simulating a collision sensor signal comprises a first database for retrieving a waveform from a lookup table, a circuit configured to scale the waveform by a first scaling factor, a second database for retrieving a predetermined road noise waveform, and a circuit configure to combine the road noise waveform with the waveform scaled by the first scaling factor, wherein the road noise waveform is based on at least one of a vehicle's speed and road quality.

According to one or more aspects of the present disclosure, the waveform is based on at least one of a material of the object and contact area of the object.

According to one or more aspects of the present disclosure, the first scaling factor is based on at least one of inertia of the object and angle of incidence.

According to one or more aspects of the present disclosure, the system further comprises a circuit configured to scale the waveform by a second scaling factor, the second scaling factor based on at least one of geometric spreading between the object collision and sensor and acoustic attenuation between the object collision and sensor.

According to one or more aspects of the present disclosure, the system further comprises a time delay circuit.

According to one aspect of the present disclosure, a method for detecting a collision in an autonomous vehicle comprises modelling a touch and collision transducer surface as a collision projection spline, the collision projection spline being a theoretical circle which partially overlaps with the autonomous vehicle, receiving touch and collision transducer signals from an array of sensors disposed on the autonomous vehicle, detecting an overlap in a collision event and surface of the autonomous vehicle, and calculating a spline distance between the collision event and closet sensor in the sensor array.

The drawings show exemplary impact emulations and configurations. Variations of these circuits, for example, changing the positions of, adding, or removing certain elements from the circuits are not beyond the scope of the present invention. The illustrated circuits, configurations, and complementary devices are intended to be complementary to the support found in the detailed description.

### BRIEF DESCRIPTION OF THE DRAWINGS

The present disclosure is best understood from the following detailed description when read with the accompanying figures. It is emphasized that, in accordance with the standard practice in the industry, various features are not necessarily drawn to scale, and are used for illustration purposes only. Where a scale is shown, explicitly or implicitly, it provides only one illustrative example. In other embodiments, the dimensions of the various features may be arbitrarily increased or reduced for clarity of discussion.

For a fuller understanding of the nature and advantages of the present invention, reference is made to the following detailed description of preferred embodiments and in connection with the accompanying drawings, in which:

FIG. 1 is a diagram illustrating an autonomous vehicle, according to some embodiments of the disclosure;

FIG. 2 is a diagram illustrating an example of a front of an autonomous vehicle having multiple transducers, according to some embodiments of the disclosure;

FIG. 3 depicts an exemplary autonomous vehicle with an illustrative collision projection spline, according to some embodiments of the disclosure;

FIG. 4 depicts an exemplary autonomous vehicle impacting a non-player character (NPC) with an illustrative collision projection spline, according to some embodiments of the disclosure;

FIG. 5 is an exemplary process for producing impact simulations, according to some embodiments of the disclosure;

FIGS. 6A-B show exemplary accelerometer measurements from an autonomous vehicle sensor array, according to some embodiments of the disclosure;

FIG. 7 is a diagram illustrating an example of a rear of an autonomous vehicle having multiple transducers, according to some embodiments of the disclosure;

FIG. 8 is a diagram of a system for detecting impacts and collisions, including multiple transducers, a data acquisition module, and a processing module, according to some embodiments of the disclosure;

FIG. 9 shows a signal processing module for processing transducer data on a vehicle, according to some embodiments of the disclosure;

FIG. 10 shows impact detection module for detecting impacts to a vehicle, according to some embodiments of the disclosure; and

FIG. 11 shows an exemplary method for monitoring the detecting impacts to a vehicle, according to some embodiments of the disclosure;

### DETAILED DESCRIPTION

### Overview

The present disclosure relates generally to the calibration of acoustic systems used in environment sensing. More specifically, the present disclosure pertains to the calibration of spatial sensing and acquisition found in autonomous vehicles. Alleviating the need to solve the wave equation or perform convolutions through expensive finite element method (FEM), simulated collision waveforms can be emulated by the following steps. Appropriate waveform is retrieved from lookup tables based on material and contact area. The retrieved waveform is scaled by a first factor to account for inertia and angle of impact incident thereby producing a first scaled waveform. The first scaled waveform is further scaled by a second factor to account for geometric spreading and attention during propagation thereby produced a second scaled waveform. This can be potentially modelled as a transfer function if filter is used. The second scaled waveform can be delayed by a predetermined time to form a delayed waveform. The delayed waveform can be combined with the appropriate road noise based at least on vehicle speed and road quality to produces a robust emulated signal of a touch and collision transducer sensor.

The following description and drawings set forth certain illustrative implementations of the disclosure in detail, which are indicative of several exemplary ways in which the various principles of the disclosure may be carried out. The illustrative examples, however, are not exhaustive of the many possible embodiments of the disclosure. Other objects, advantages and novel features of the disclosure are set forth in the proceeding in view of the drawings where applicable.

Autonomous vehicles, also known as self-driving cars, driverless vehicles, and robotic vehicles, are vehicles that use multiple sensors to sense the environment and move without human input. Automation technology in the autonomous vehicles enables the vehicles to drive on roadways and to accurately and quickly perceive the vehicle's environment, including obstacles, signs, and traffic lights. The vehicles can be used to pick up passengers and drive the passengers to selected destinations. The vehicles can also be used to pick up packages and/or other goods and deliver the packages and/or goods to selected destinations.

Autonomous vehicles are often used in rideshare services and spend many hours per day on the road. While driving on public roadways, it is possible that an autonomous vehicle may collide with an object, vehicle, or person. Additionally, pedestrians, bicyclists, skateboarders, and others may graze by or otherwise touch the autonomous vehicle. Some jurisdictions require autonomous vehicles to record audio and video for a period of time surrounding all types of collisions.

Some impact detection systems rely on camera and LiDAR data, and have relatively high false positive rates. Upon detection of an impact, a remote-assist protocol (involving a remote live operator) is activated. With many vehicles in a fleet, these systems can include a high level of human involvement and become very expensive. Less expensive and more accurate systems are needed for detecting and identifying vehicle surface impacts.

Many different types of impacts and collisions can occur while an autonomous vehicle is driving around. For example, a bicyclist, pedestrian, skateboarder, rollerblader, scooter-driver, or other person may move close to a vehicle and touch an exterior of the vehicle. Additionally, an autonomous vehicle can be rear-ended or side-swiped by another vehicle. Furthermore, an object from the road can hit the autonomous vehicle, such as road debris propelled by another vehicle, and/or something can fall onto the vehicle such as an acorn or branch. In some examples, an object on the road (such as a plastic bag or tree branch) can become attached to the vehicle, resulting in the vehicle dragging the object around as it drives.

Collision detection, identification and analysis is a complex and computationally intensive endeavor. Object material, momentum, angle of incident, and location all contribute to varying waveform signals produced by touch and collision transducer sensors. Rigorous analysis using the wave equation in the time-domain and/or convolution in the frequency domain are both untenable.

The wave equation is a second-order linear partial differential equation for the description of waves—as they occur in classical physics—such as mechanical waves (e.g. water waves, sound waves and seismic waves) or electromagnetic waves (including light waves). The wave equation arises in fields like acoustics, electromagnetism, and fluid dynamics. Convolution is a mathematical operation on two functions (f and g) that produces a third function (f*g) that expresses how the shape of one is modified by the other. The term convolution refers to both the result function and to the process of computing it. It is defined as the integral of the product of the two functions after one is reversed and shifted. The integral is evaluated for all values of shift, producing the convolution function.

The inventors of the present disclosure have identified numerous shortcomings found in the state of the art. Previous efforts comprise physically recording a variegated array of sounds. However, this is laborious and unwieldy. The inventors of the present disclosure bootstrap the availability of limited number of waveforms and make the applicable to a wide variety of circumstances and/or materials. The inventors of the present disclosure have recognized the long felt need for a more robust detection techniques to mitigate false positive and ameliorate detection analysis to overcome the deficiencies of the state of the art, at least in part.

Systems and methods are provided to combine lookup tables for waveforms and several scaling and delay factors to accurately simulate touch and collision transducer sensor output without the complexity of solving the classical wave equation or performing convolutions in the frequency domain. The waveform can take many forms depending on various parameter. Pre-recorded waveforms can be used to simulate the collisions and produce appropriate outputs. However, the present disclosure contemplates more complex, diverse waveforms which can be produced based on the existing pre-recorded libraries. To this end, simulated waveforms can be produced by scaling, filtering, delaying, and combining with road noise, based on the impact material and contact area, at least in part.

### Example Autonomous Vehicle Configured for Collision Detection

Autonomous vehicles, also known as self-driving cars, driverless vehicles, and robotic vehicles, are vehicles that use multiple sensors to sense the environment and move without human input. Automation technology in the autonomous vehicles enables the vehicles to drive on roadways and to accurately and quickly perceive the vehicle's environment, including obstacles, signs, and traffic lights. The vehicles can be used to pick up passengers and drive the passengers to selected destinations. The vehicles can also be used to pick up packages and/or other goods and deliver the packages and/or goods to selected destinations. Autonomous vehicles rely heavily on optical systems which are accurate for classification. That is, the vehicle relies upon this analysis to distinguish between threats and benign classification of targets.

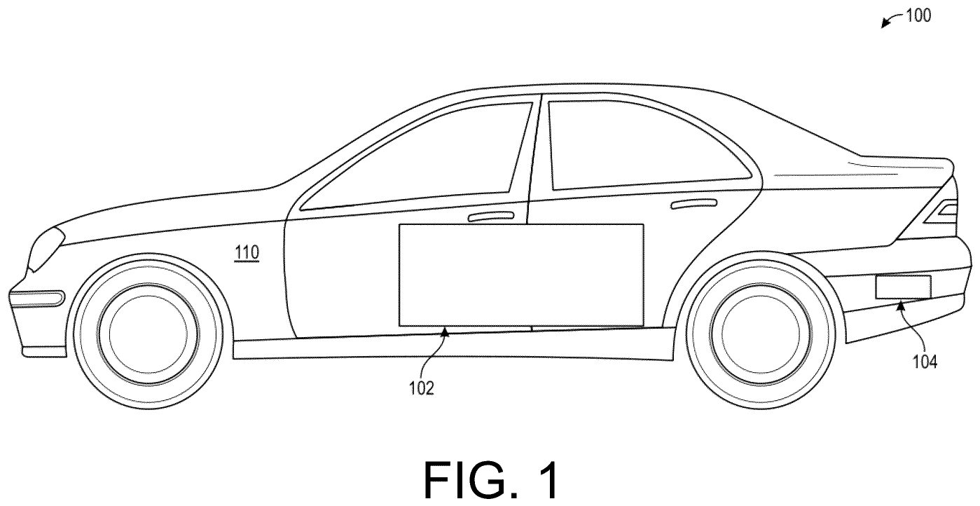

FIG. 1 is a diagram of an autonomous driving system 100 illustrating an autonomous vehicle 110, according to some embodiments of the disclosure. The autonomous vehicle 110 includes a sensor suite 102 and an onboard computer 104. In various implementations, the autonomous vehicle 110 uses sensor information from the sensor suite 102 to determine its location, to navigate traffic, and to sense and avoid obstacles. According to various implementations, the autonomous vehicle 110 is part of a fleet of vehicles for picking up passengers and/or packages and driving to selected destinations.

The sensor suite 102 includes localization and driving sensors. For example, the sensor suite may include one or more of photodetectors, cameras, radar, sonar, lidar, GPS, inertial measurement units (IMUs), accelerometers, microphones, strain gauges, pressure monitors, barometers, thermometers, altimeters, wheel speed sensors, and a computer vision system. The sensor suite 102 continuously monitors the autonomous vehicle's environment and, in some examples, sensor suite 102 data is used to detect selected events, and update a high-fidelity map. In particular, data from the sensor suite can be used to update a map with information used to develop layers with waypoints identifying selected events, the locations of the encountered events, and the frequency with which the events are encountered at the identified location. In some examples, the events include road hazard data such as locations of pot holes or debris. In this way, sensor suite 102 data from many autonomous vehicles can continually provide feedback to the mapping system and the high-fidelity map can be updated as more and more information is gathered.

The sensor suite 102 includes a plurality of sensors and is coupled to the onboard computer 104. In some examples, the onboard computer 104 receives data captured by the sensor suite 102 and utilizes the data received from the sensors suite 102 in controlling operation of the autonomous vehicle 110. In some examples, one or more sensors in the sensor suite 102 are coupled to the vehicle batteries, and capture information regarding a state of charge of the batteries and/or a state of health of the batteries.

In various examples, the sensor suite 102 includes cameras implemented using high-resolution imagers with fixed mounting and field of view. In further examples, the sensor suite 102 includes lidars implemented using scanning lidars. Scanning lidars have a dynamically configurable field of view that provides a point-cloud of the region intended to scan. In still further examples, the sensor suite 102 includes radars implemented using scanning radars with dynamically configurable field of view. In some examples, the sensor suite 102 records information relevant to vehicle structural health. In various examples, additional sensors are positioned within the vehicle, and on other surfaces on the vehicle. In some examples, additional sensors are positioned on the vehicle chassis.

The autonomous vehicle 110 includes an onboard computer 104, which functions to control the autonomous vehicle 110. The onboard computer 104 processes sensed data from the sensor suite 102 and/or other sensors, in order to determine a state of the autonomous vehicle 110. In some implementations described herein, the autonomous vehicle 110 includes sensors inside the vehicle. In some examples, the autonomous vehicle 110 includes one or more cameras inside the vehicle. The cameras can be used to detect items or people inside the vehicle. In some examples, the autonomous vehicle 110 includes one or more weight sensors inside the vehicle, which can be used to detect items or people inside the vehicle. Based upon the vehicle state and programmed instructions, the onboard computer 104 controls and/or modifies driving behavior of the autonomous vehicle 110.

The onboard computer 104 functions to control the operations and functionality of the autonomous vehicle 110 and processes sensed data from the sensor suite 102 and/or other sensors in order to determine states of the autonomous vehicle. In some implementations, the onboard computer 104 is a general-purpose computer adapted for I/O communication with vehicle control systems and sensor systems. In some implementations, the onboard computer 104 is any suitable computing device. In some implementations, the onboard computer 104 is connected to the Internet via a wireless connection (e.g., via a cellular data connection). In some examples, the onboard computer 104 is coupled to any number of wireless or wired communication systems. In some examples, the onboard computer 104 is coupled to one or more communication systems via a mesh network of devices, such as a mesh network formed by autonomous vehicles.

According to various implementations, the autonomous driving system 100 of FIG. 1 functions to enable an autonomous vehicle 110 to modify and/or set a driving behavior in response to parameters set by vehicle passengers (e.g., via a passenger interface) and/or other interested parties (e.g., via a vehicle coordinator or a remote expert interface). Driving behavior of an autonomous vehicle may be modified according to explicit input or feedback (e.g., a passenger specifying a maximum speed or a relative comfort level), implicit input or feedback (e.g., a passenger's heart rate), or any other suitable data or manner of communicating driving behavior preferences.

The autonomous vehicle 110 is preferably a fully autonomous automobile, but may additionally or alternatively be any semi-autonomous or fully autonomous vehicle. In various examples, the autonomous vehicle 110 is a boat, an unmanned aerial vehicle, a driverless car, a golf cart, a truck, a van, a recreational vehicle, a train, a tram, a three-wheeled vehicle, or a scooter. Additionally, or alternatively, the autonomous vehicles may be vehicles that switch between a semi-autonomous state and a fully autonomous state and thus, some autonomous vehicles may have attributes of both a semi-autonomous vehicle and a fully autonomous vehicle depending on the state of the vehicle.

In various implementations, the autonomous vehicle 110 includes a throttle interface that controls an engine throttle, motor speed (e.g., rotational speed of electric motor), or any other movement-enabling mechanism. In various implementations, the autonomous vehicle 110 includes a brake interface that controls brakes of the autonomous vehicle 110 and controls any other movement-retarding mechanism of the autonomous vehicle 110. In various implementations, the autonomous vehicle 110 includes a steering interface that controls steering of the autonomous vehicle 110. In one example, the steering interface changes the angle of wheels of the autonomous vehicle. The autonomous vehicle 110 may additionally or alternatively include interfaces for control of any other vehicle functions, for example, windshield wipers, headlights, turn indicators, air conditioning, etc.

### Example Vehicle Front with Accelerometers

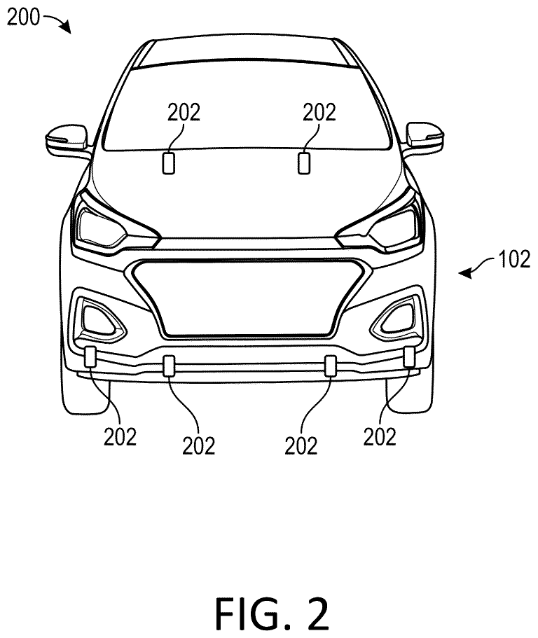

FIG. 2 is a diagram illustrating an example of a front of an autonomous vehicle 200 with multiple transducers 202, according to various embodiments of the invention. The transducers 202 are positioned underneath the fascia of the vehicle, such that they are not visible from the exterior. In some examples, the transducers 202 are positioned on the back side (“B-Side”) of the fascia and door panels, and/or nearby sheet-metal inner panels. In various implementations, more or fewer transducers 202 are included on the vehicle 200, and in various implementations, the transducers 202 are located in any selected position on or in the vehicle 200. The transducers 202 are positioned and designed to detect impacts and collisions with a surface of the autonomous vehicle 200.

According to various implementations, one or more of the transducers 202 are piezoelectric transducers. Piezoelectric transducers convert physical quantities into an electrical signal. In some examples, the piezoelectric transducers are deformation-based transducers. The deformation of the transducer is proportional to acceleration and/or strain. In some examples, the piezoelectric transducers are used to measure changes in one or more of pressure, acceleration, force, strain, and temperature via the piezoelectric effect. Piezoelectric transducers can be designed to measure changes along any axis and in some examples, the piezoelectric transducers are 3-axis transducers. In other examples, the piezoelectric transducers are 6-axis transducers. In various examples, the piezoelectric transducers can measure changes along any number of axes. Various modes of operation of the piezoelectric transducers include transverse, longitudinal, and shear. In some implementations, the piezoelectric transducers include a voltage source which changes in proportion to an applied force, pressure, or strain. In some examples, the piezoelectric transducers produce an electric voltage that can be measured to calculate the value of stress or strain applied to a material.

In some implementations, one or more of the transducers 202 are accelerometers. The accelerometers are very sensitive, and can provide impact detection information, for example by comparing sensed data from multiple transducers. In some implementations, one or more of the transducers 202 are and/or include microphones. In various implementations, one or more of the transducers 202 are permanently integrated into and/or onto the structure of the vehicle. In some examples, one or more transducers 202 are added to the autonomous vehicle 200 temporarily and/or at a later date, after the vehicle has been in service for some period of time.

According to various implementations, the transducers 202 generate information such as vibration profiles and impulse responses.

In various examples, transducers including accelerometers are positioned in multiple locations on the interior fascia of a vehicle. Accelerometer data from various locations can be combined to detect impacts. In some examples, data from an internal inertial sensor mounted to the vehicle frame (IMU) is combined with B-surface transducer 202 data to detect impacts. In particular, the inertial sensor data can be used to determine whether transducer deviations are caused by road noise, wind noise, speed bumps, and/or other non-impact-related variations. Additionally, data from multiple surface transducers 202 is compared to determine impact location. In particular, in some examples, an impact at a selected location will create the greatest deviation in transducer data from the transducers closest to the impact location, while transducers further from the impact location have a smaller deviation in transducer data, at a slightly later time, allowing for triangulation. By analyzing deviations in data at multiple transducers, the location of the impact can be determined.

In some implementations, energy captured by one or more of the transducers 202 on the back of the fascia (on the B-Side or B-Surface) is compared with energy captured by one or more other of the transducers 202. Additionally, in some implementations, energy captured by one or more of the transducers 202 on the back of the fascia is compared with the IMU data. In some examples, these comparisons are done via a coherence calculation. In some examples, the part of the spectra where the coherence approaches one is ignored, because of increased likelihood that the part of the spectra where coherence approaches one is caused by accelerations that originated with the power-train and suspension, as opposed to through impact of a B-surface transducer.

In various examples, the transducers 202 are permanently installed on the vehicle, and typical transducer responses to road features, including a spectrum of the response of each transducer, is recorded and saved. Furthermore, relationships between the transducers are recorded. In some examples, typical transducer responses including relationships between transducers from road testing and structured impact testing, are saved in a lookup table. The lookup table can be used to determine an impact location and absolute impact energy, based on variations in data from multiple transducers. In some examples, a transfer function is used to characterize a relationship between certain elements

In some implementations, the transducers 202 include accelerometers that have a fine resolution and excellent DC-offset stability, allowing the transducers 202 to infer the gravity vector. Inferring the gravity vector enables confirmation that the transducer is still attached to the vehicle in its selected location. Additionally, inferring the gravity vector enables detection of towing.

In some implementations, when the autonomous vehicle is generally powered down, some modules remain awake in a low powered state. Simple threshold and deformation processing, with heuristics about the duration and intensity of the disturbance detected by the transducers 202, are used to detect vandalism, tampering, and towing. When these activities are detected, a message is sent to another module to wake up the vehicle for logging of camera and audio data, as well as to wirelessly report back to a central computer.

### Example Vehicle with Touch and Collision Transducer Signaling

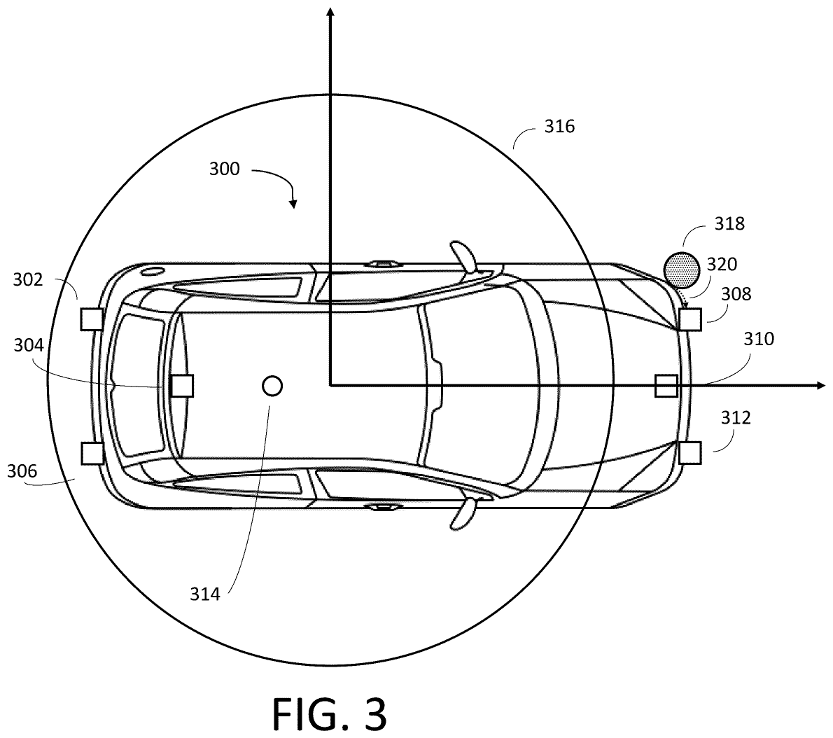

FIG. 3 depicts an exemplary autonomous vehicle with an illustrative collision projection spline, according to some embodiments of the disclosure. Autonomous vehicle 300 comprises chassis frame 314, rear left transducer 302, rear upper transducer 304, rear right transducer 306, front left transducer 308, front upper transducer 310, front right transducer 312.

Touch and collision transducer collision signals can be generated in the following manner. Touch and collision transducer signals can be “spoofed” using the touch and collision transducer signal generator. In one or more embodiments the present disclosure employs a game engine to model on or more parameters, objects and/or events. Accordingly, the spoofing process comprises the following ingredients. An “overlap” is detected between an autonomous vehicle mesh and NPC shape. This is a collision event. The autonomous vehicle mesh refers to a 3D mesh which can be the structural build of a 3D model consisting of polygons. 3D meshes use reference points in X, Y, and Z axes to define shapes with height, width, and depth. Colloquially, a NPC typically refers to any substantive object other than the autonomous vehicle itself. Frequently, the NPC refers to the impact object. This will be discussed in greater detail in later in the disclosure.

Continuing with the ingredients, basic collision information is collected and sent to communication bridge in the modelling engine. The signal data is conveyed to an engine bridge in an autonomous vehicle stack process. This basic information of the signal data currently comprises, at least in part: Timestamp; Relative velocities; Collision normal (as determined below); Car Velocity; and spline distances to touch and collision transducer Sensors and Collision Object Mass.

During the autonomous vehicle process, the information is deconstructed and fed into the touch and collision transducer signal generator. Broadly the touch and collision transducer signal generator uses the spline distances, normal, relative velocity, etc., to generate a signal. More specifically, the touch and collision transducer signal generator use the above information to calculate scaling factors and time delay for the signals extracted from the lookup table. The geometry and methodology are discussed in greater detail below. In practice, the output data from the signal can used to create the same data packet format as a real sensor. In other embodiments, the data packet can replicate certain characteristic parameters, variables, and characteristics. FIG. 3 is a diagram of the geometric model used by the touch and collision transducer Sensor Component for computing spline distances and collision normals. Touch and collision transducer sensors are placed in the plane of the chassis coordinate system according to the following locations: rear left transducer 302, rear upper transducer 304, rear right transducer 306, front left transducer 308, front upper transducer 310, front right transducer.

In practice, a NPC 318 event comes in contact with autonomous vehicle 300. Consequently, an acoustic wave propagates from the source to the observer. In the present example, a contact and/or impact from the NPC produces a wave which radiates outwards from the impact site. One skilled in the art can appreciate that the wave propagation can become very complex in that many parameters and boundary conditions come into play. These include the acoustic impedances of the material, the phase and group velocities of the wave vector, the air/AV interface, the boundaries by which the wave crosses, etc. However, the inventors of the present disclosure make use of several abstractions which simplify the calculation of the wave propagation.

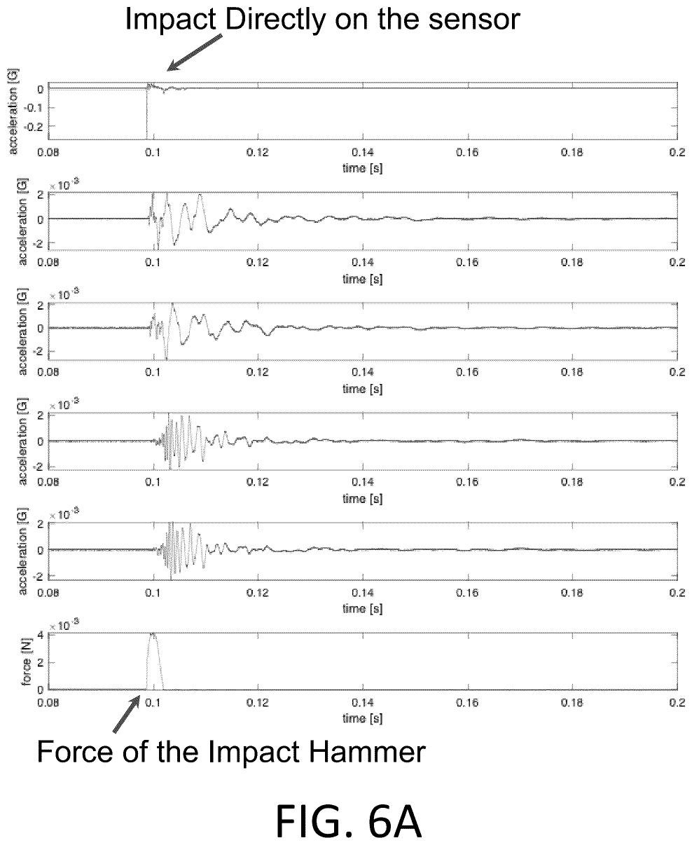

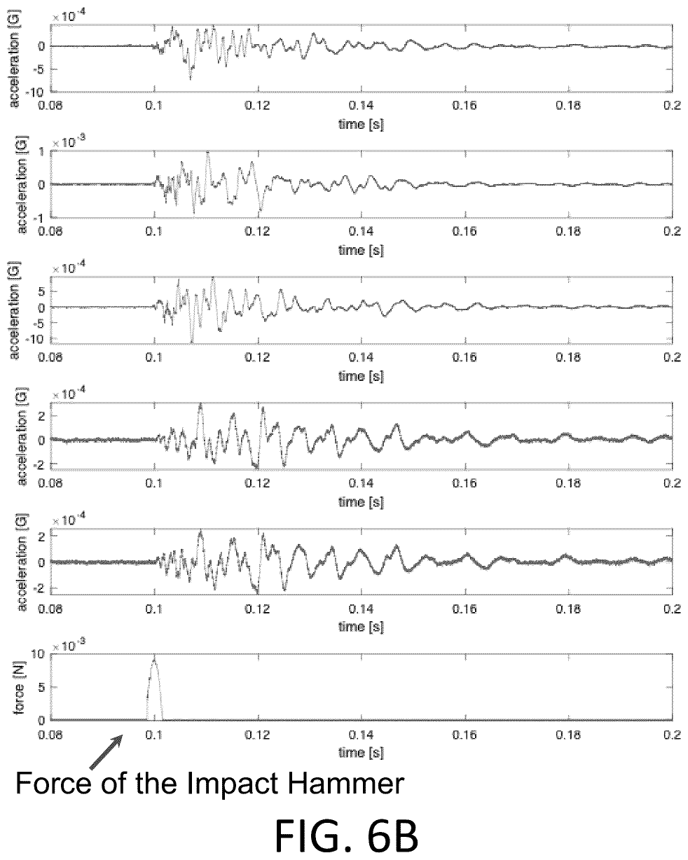

It can be assumed that most of the impact energy is absorbed by the autonomous vehicle 300, in that the acoustic energy dissipated by the ambient air is negligible. Next, each autonomous vehicle 300 panel can be lumped into a single medium having a wave propagation speed (group velocity). This can either be determined analytically or empirically. Also, the time delay which the wave front 320 reaches the closest TACT sensor 308 is dependent on the shortest pathlength along the surface of the autonomous vehicle 300 panel. This will be discussed in greater detail in association with FIG. 6. In one or more embodiments, the geodesic distance from source to sensor can be used to improve distance calculations.

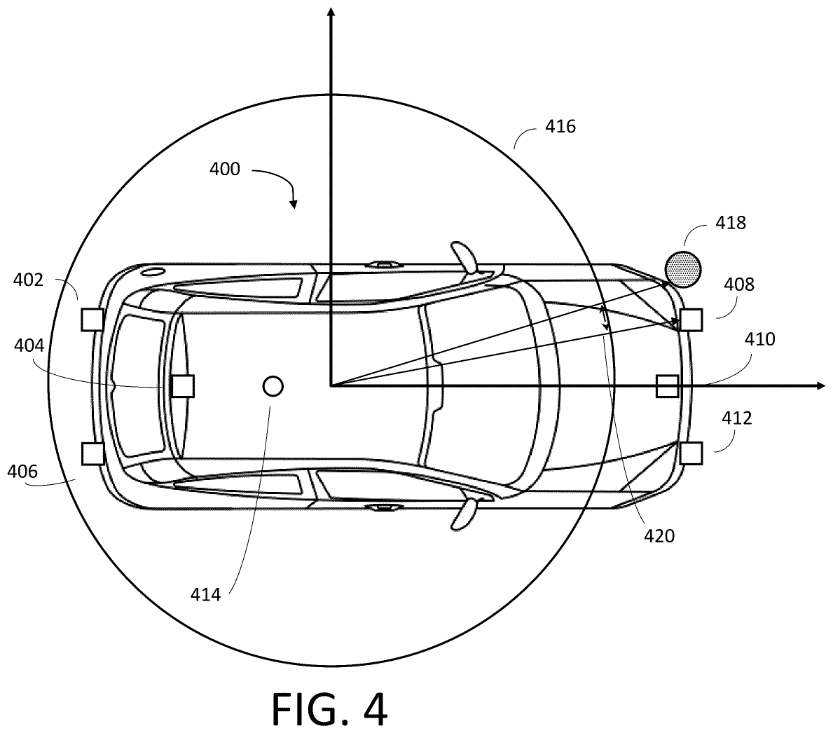

In one or more embodiments, orientations can be ignored. Surface normal are used for calculating the scaling factor S1 which will be discussed later in the disclosure. It is defined as the outward normal direction of the collision surface. Also, collision normals are interpreted in the chassis frame, in some embodiments. Determination of collision normal and spline distances are calculated as follows. As can be appreciated by one skilled in the art, the distance within the TACT conductive surface between a collision location and each of the TACT transducers is referred to as the “spline distance.” This is roughly the distance the touch and collision transducer signal propagates from source to detector. These spline distances are calculated using the simplified geometry depicted in FIGS. 3-4. The touch and collision transducer sensors are viewed as having their locations determined in a 2D plane as specified above. We model the touch and collision transducer surface as a collision projection spline 316.

FIG. 4 depicts an exemplary autonomous vehicle 400 impacting a NPC 418 with an illustrative collision projection spline 416, according to some embodiments of the disclosure. Autonomous vehicle 400 comprises chassis frame 414, rear left transducer 402, rear upper transducer 404, rear right transducer 406, front left transducer 408, front upper transducer 410, front right transducer 412.

The plurality of transducers 402-412 can be used to determine the location of an acoustic event based at least on the differences in time delays. Event location can be used to determine whether a touch or collision occurred with the autonomous vehicle. For example, acoustic events, such as, dropping a bicycle, close to the autonomous vehicle could be excluded from collision determination. In practice, when the vehicle detects an overlap between the autonomous vehicle chassis and NPC 418 event, the difference in positions of the car and the NPC are used to calculate a collision normal. Given this normal, for each of the touch and collision transducer transducers we calculate the relative angle to the horizontal plane-projected transducer location. This relative angle is then projected on the collision projection spline, currently modelled as a circle of radius 2 m, although other radii are not beyond the scope of the current disclosure. The arc-length 420 on the circle are taken to be the spline distances input to the TACT Signal Generator, per FIG. 4.

Specifically, spline distance can be used to calculate scaling factor S2 and time delay, which will be discussed later in the disclosure. As previously discussed, time delay can be defined as the distance between the collision location of NPC 418 and touch and collision transducer sensor location projected onto the vehicle body surface. As can be appreciated by one skilled in the art, arc-length and spline distance are intimately related and roughly equal if using a small angle approximation. Arc-length a function of radius can be used to approximate wave front time delay. In practice, spline distances can also be used to estimate propagation times and paths to the touch and collision transducer sensors which are further away from the initial impact.

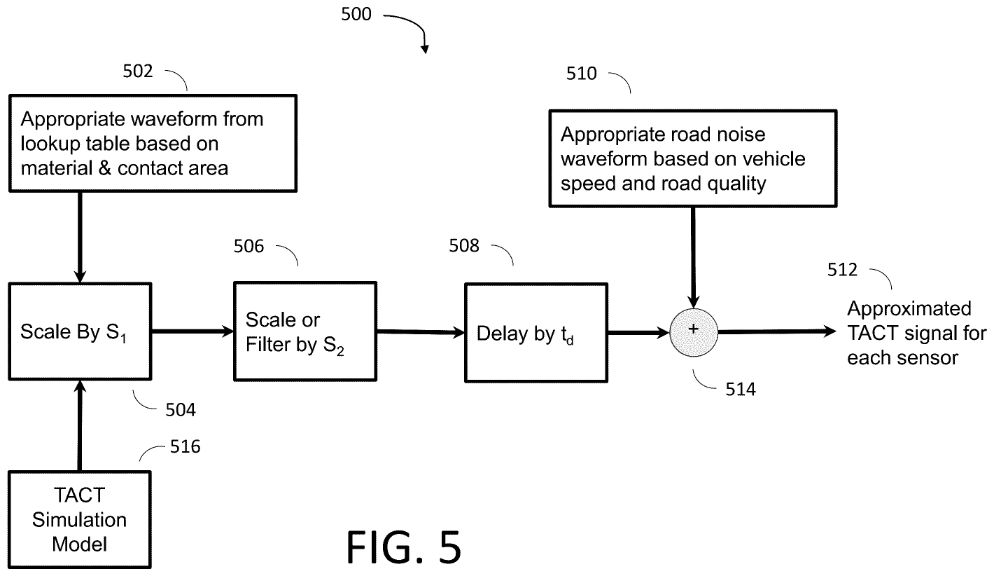

FIG. 5 is an exemplary process for producing impact simulations, according to some embodiments of the disclosure. The present disclosure builds upon existing tap/knock and structured crash waveform libraries. Tap/knock and structured crash waveforms are used during autonomous vehicle machine learning and in impact classification. In practice, it is important for an autonomous vehicle to delineate between varying contacts, whether it be a benign plastic bag blowing against the vehicle or pedestrian impact. Existing tap/knock and structured crash waveform libraries can be used to manufacture an inexhaustible range of scenarios and materials, something which can't be done in the present state of the art.

The inventors of the present disclosure contemplate the following process which is represented in FIG. 5. Without solving the wave equation, or performing convolution through computationally intensive FEM, the method is a proposed first pass to simulating touch and collision transducer data. Select the appropriate waveform from lookup table based on material and contact area 502. Typical materials comprise tissue, bone, wood, metal, polymers, and composites, but any material is not beyond the scope of the present disclosure. Objects of the present disclosure can focus on false thigh, bicycle tire, bicycle frame, impact hammer, and hands. Contact areas can refer to surface area or impact location or both. In the present embodiment, the lookup table is volatile memory. Yet any computer data storage is not beyond the scope of the present invention, such as, but not limited to, random access memory (RAM), non-volatile read only memory (ROM), non-volatile RAM (NVRAM), analog recording, and/or optical storage.

Scale by S₁ 504 comprises S₁ scaling accounts for inertia and angle of incidence. For example, kinetic energy and/or momentum can be compensated for if a larger or smaller impact simulation is desired. In some embodiments, this is a linear scaling while in others, the scaling can be a more complex polynomial or non-linear scaling. For the first pass, the inventors propose three variables first order variables (relative speed, object mass and angle of impact) be combined into a single factor for scaling an acceleration waveform, S₁:

S₁∝m\vec{v}·\vec{N}

where, m: mass of the object, V: is the relative velocity vector, and N: is the surface normal vector.

Modelling can be performed by touch and collision transducer simulation model 516. The touch and collision transducer signal model can use the signal data parameters, e.g., collision object mass, velocity, etc., to calculate scaling factors and time delay for the signals extracted from the lookup table.

Scale or Filter by S₂ 506. S₂ accounts for geometric spreading and attenuation during propagation. As the sound moves away from the source, the area that the sound energy covers become larger and thus sound intensity decreases. This is referred to as “geometric spreading,” which is independent of frequency and plays a major role in sound propagation situations. Due to geometric spreading, the sound level is reduced by 6 dB and 3 dB for each doubling of distance from the point (e.g., fixed equipment) and line (e.g., road traffic) sources, respectively.

In a homogeneous medium, energy density decays proportionately to 1/r², where r is the radius of the wavefront. Wave amplitude is proportional to the square root of energy density; it decays as 1/r. In practice, velocity usually increases with depth, which causes further divergence of the wavefront and a more rapid decay in amplitudes with distance. The frequency content of the initial source signal changes in a time-variant manner as it propagates. In particular, high frequencies are absorbed more rapidly than low frequencies. This is because of the intrinsic attenuation autonomous vehicle material. As such S₂ potentially includes a transfer function if filtering is used.

In practice, distance of an impact site from the transducer (accelerometer) is compensated for as follows. This variable (distance) influences the magnitude of the impact, as the further the sensor from the source, the less energy reaches the sensor. First order cylindrical spreading is calculated as follows:

$${S}_{2} ∝ \frac{1}{\sqrt{d}}$$

where S₂ is the scaling factor and d is distance between the impact site and first transducer.

As discussed, propagation absorption is generally higher at higher frequencies. However, any spectra are not beyond the scope of the present disclosure. As a second-order correction, a frequency dependent attention is compensated by one or more filters. In signal processing, a filter is a device or process that removes some unwanted components or features from a signal. Filtering is a class of signal processing, the defining feature of filters being the complete or partial suppression of some aspect of the signal. Most often, this means removing some frequencies or frequency bands.

Without limitation, the filter can be one or more of the following types: non-linear or linear; time-variant or time-invariant, also known as shift invariance (if the filter operates in a spatial domain then the characterization is space invariance); causal or non-causal, as filters processing time-domain signals in real time can be causal, but not filters acting on spatial domain signals or deferred-time processing of time-domain signals; analog or digital; discrete-time (sampled) or continuous-time; passive or active type of continuous-time filter; and, infinite impulse response (IIR) or finite impulse response (FIR) type of discrete-time or digital filter.

In practice, a high pass filter (linear continuous-time) can be used in conjunction with a linear amplification. In the context of the present disclosure, this can be modelled using a transfer function. A transfer function (also known as system function or network function) of a system, sub-system, or component is a mathematical function which theoretically models the system's output for each possible input. In one or more embodiments, the transfer function is the frequency domain analysis of the system using transform methods such as the Laplace transform. As such, the amplitude of the output as a function of the frequency of the input signal. For example, the transfer function of an electronic filter is the voltage amplitude at the output as a function of the frequency of a constant amplitude sine wave applied to the input.

In some embodiments, the transfer function can account for dispersive media. Dispersion is the phenomenon in which the phase velocity of a wave depends on its frequency, while maintaining a constant group velocity. Media having this common property may be termed dispersive media. Sometimes the term chromatic dispersion is used for specificity. Acoustic dispersion is the phenomenon of a sound wave separating into its component frequencies as it passes through a material. The phase velocity of the sound wave is viewed as a function of frequency. Hence, separation of component frequencies is measured by the rate of change in phase velocities as the radiated waves pass through a given medium.

At the third order of analysis, the inventors proposed the application of laser vibrometry. A Laser Doppler vibrometer (LDV) is a scientific instrument that is used to make non-contact vibration measurements of a surface. The laser beam from the LDV is directed at the surface of interest, and the vibration amplitude and frequency are extracted from the Doppler shift of the reflected laser beam frequency due to the motion of the surface. The output of an LDV is generally a continuous analog voltage that is directly proportional to the target velocity component along the direction of the laser beam. When applied to all over a surface, the LDV response can be used as a scaling factor.

Turning back to FIG. 5, delay by td controls the timing of the impact and calculated as follows: t_{d}(sensor #)=d(sensor #)/cₒ, where, cₒ: speed of sound—predetermine constant tangent to the surface, and t_{d}(sensor #): time delay between the moment of impact and the arrival time at each sensor.

The delayed result of 508 gets added 514 to predetermined road noise. Appropriate road noise waveform based on vehicle speed and road quality 510 comprises accessing a lookup table/array/matrix and retrieving a noise waveform for an autonomous vehicle based on vehicle speed and road quality. The end result is an approximated touch and collision transducer signal for each sensor 512.

In one or more embodiments, the modelling substantially remains in the linear regime and 1st order approximations with the goal of accurately representing the following features without solving the wave equation. The preferred parameters include peak acceleration, timing of impact, noise floor, frequency content of impact, and frequency content of chassis motion.

### Exemplary Hammer Impacts in the Time-Domain

FIGS. 6A-B show exemplary accelerometer measurements from an autonomous vehicle sensor array, according to some embodiments of the disclosure. FIGS. 6A-B are illustrative of a plurality of received sensor measurements. The bottom row demonstrates the impulse response stemming from the force a hammer blow as a function of time. (Ideally, this would be represented by a delta function.) The top row corresponds to a touch and collision transducer sensor which has been directly impacted by the hammer. One can appreciated the small, if any, measured time delay. The progressive rows represent reception and measurement of subsequent sensors. These sensors are geodesically further away from the impact site.

In one or more embodiments, the congruence and concert of time delays can be used to triangulate impact/contact location. While three sensors are typically necessary for 3-dimensional triangulation (e.g., GPS), two sensor information can suffice in location position in most cases. In practice, this predetermined knowledge can be used to create a plurality of sensor simulations with variegated time delays.

### Example Vehicle Rear with Transducers

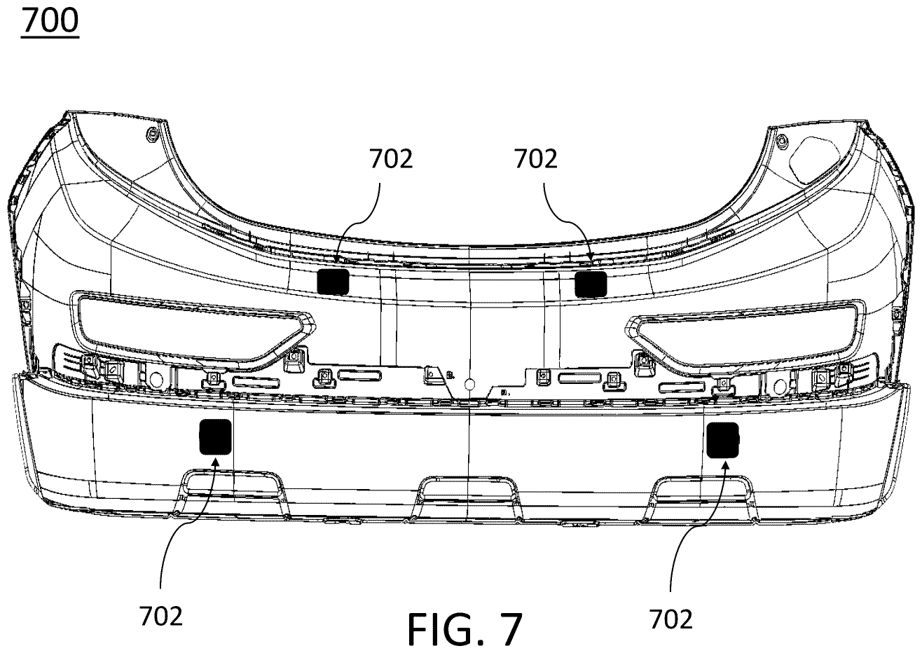

FIG. 7 is a diagram illustrating an example of a rear of an autonomous vehicle 700 with multiple transducers 702, according to various embodiments of the invention. The transducers 702 are positioned underneath the fascia of the vehicle, such that they are not visible from the exterior. In various implementations, more or fewer transducers 702 are included on the vehicle 700, and in various implementations, the transducers 702 are located in any selected position on or in the vehicle 700. The transducers 702 are positioned and designed to detect contact, impacts, and collisions with a surface of the autonomous vehicle 300. As described above with respect to the transducers 202 of FIG. 2, in various examples, one or more of the transducers 702 are piezoelectric transducers, multi-axis piezoelectric transducers, accelerometers, multi-axis accelerometers, microphones.

In various implementations, additional transducers 702 are positioned along the sides of an autonomous vehicle. Also, in some examples, additional transducers 702 are positioned at the rear of the autonomous vehicle. These transducers may also be positioned underneath the fascia of the vehicle. A subset of transducers may be placed on the suspension, or the main vehicle inertial measurement unit may be used in order to determine whether the source of acceleration is the suspension, or drive train, based on time delays of correlated acceleration waveforms.

Responses among the various transducers 702 are used to detect impacts and collisions with the vehicle, at least in part by detecting deviations from typical patterns. Additionally, the data from the transducers 702 can be combined with data from the transducers 202 of FIG. 2 as well as with data from transducers on the sides, rear, interior, frame, and other locations on the vehicle, to generate response patterns and detect anomalies and/or deviations.

### Example System for Impact Detection

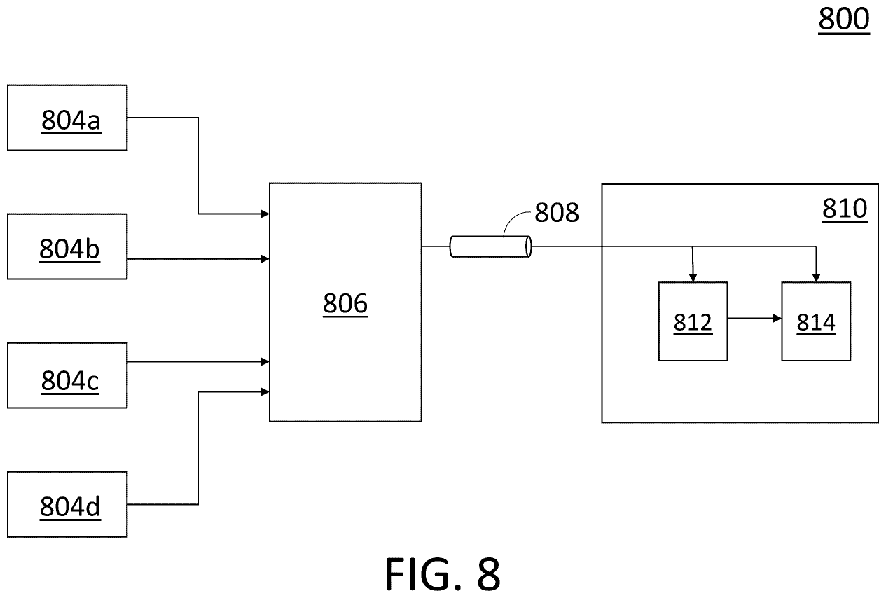

FIG. 8 is a diagram 800 of a system for detecting impacts and collisions, including multiple transducers 804a-804d, a data acquisition module 806, and a processor 810, according to various embodiments of the disclosure. The transducers 804a-804d generate transducer data as described above with respect to FIGS. 2 and 7. Each of the transducers 804a-804d are connected on a bus, and transducer data is transmitted to a data acquisition module 806. In various implementations, a bus includes more than four transducers. The transducer data is generated as analog or digital data in the sensor, and in some examples, the analog transducer data is converted to a digital signal at an analog-to-digital converter on the bus. A transceiver transmits the data from the bus to the data acquisition module.

The transducer 804a-804d data is received at the data acquisition module 806, which collects the data from multiple transducers 804a-804d, and from multiple busses. In some examples, the data acquisition module 806 filters the transducer data. In some examples, the data acquisition module performs pre-processing filtering on the transducer data. In one example, the data acquisition module 806 is a FPGA-based (field programmable gate array-based) module and includes one or more filters for filtering the received transducer data. In some implementations, the data acquisition module 806 determines whether deviations and outliers in 804a-804d transducer data are caused by a vandalism event. In some examples, vandalism occurs when the vehicle is stationary. In some implementations, the data acquisition module 806 determines whether deviations and outliers in transducer 804a-804d data are caused by the vehicle being towed.

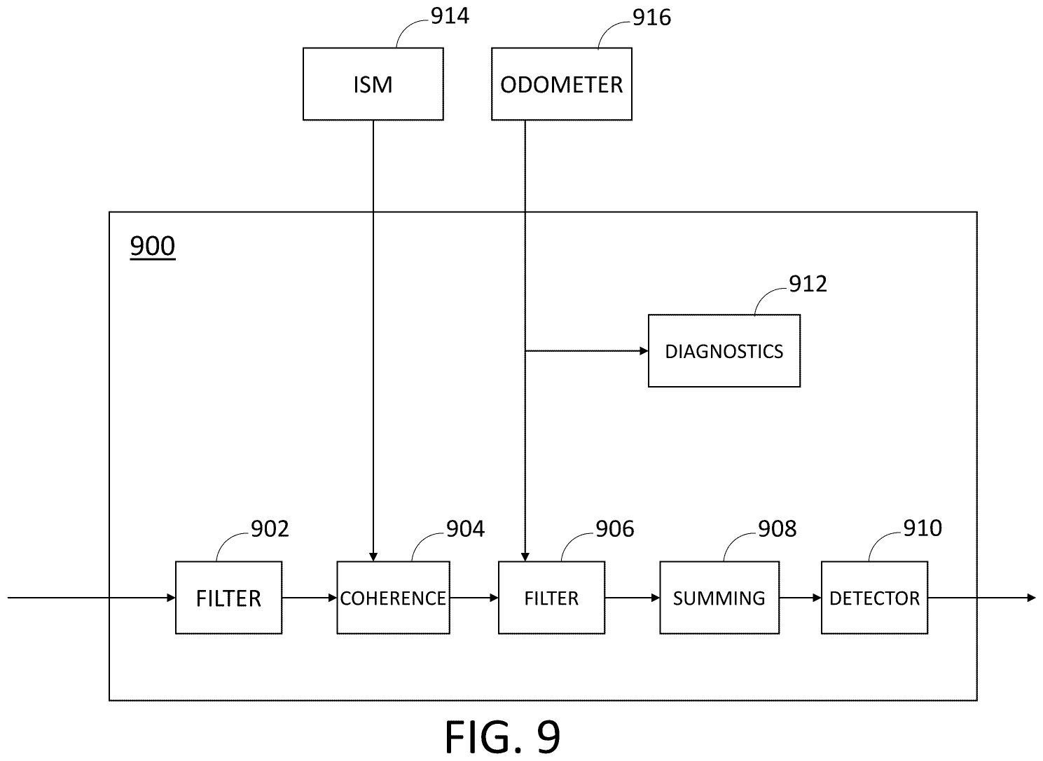

The data acquisition module 806 is connected to a processor 810 via a connection 808. In some examples, the connection 808 is one of an ethernet connection, an optical cable connection, and a wireless connection. The processor 810 receives the filtered transducer data from the data acquisition module 806, as well as data from a vehicle sensor suite, such as the sensor suite 102 in FIG. 1, vehicle odometer data, and Inertial Sensing Module (ISM) communication data. The processor 810 includes a signal processing module 812 and an impact detection module 814, and using the various input data, the processor 810 determines whether an impact is detected. The processor 810 performs signal processing on the filtered data at a signal processing module 812, as described below with respect to FIG. 9.

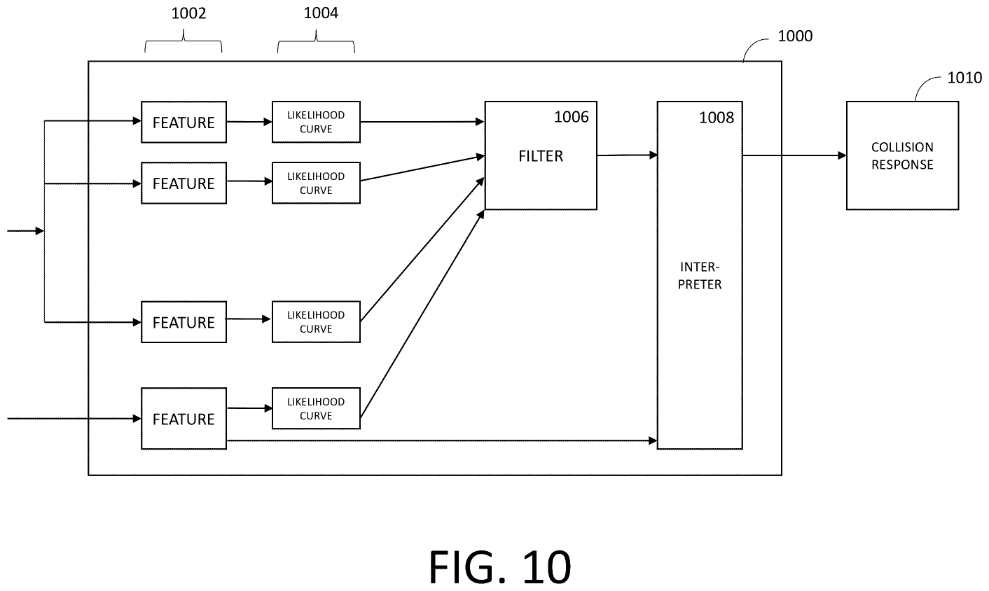

In some examples, the processor 810 performs digital signal processing on the filtered data. Additionally, the processor 810 includes an impact detection module 814, as described below with respect to FIG. 10. The impact detection module 814 receives the filtered transducer data from the acquisition module 806. In some examples, impact detection module 814 receives raw data. In some examples, the impact detection module 814 receives filtered data, and in particular data with noise filtered out, as described below with respect to FIG. 9. In some examples, the impact detection module 814 also receives the processed data from the signal processing module 812.

In some examples, the transducer data includes a spectrum of data that can be divided into multiple bands, and a transfer function can be used to evaluate each of the bands. In one example, the spectrum is divided into twelve octave bands, and a twelve-octave band transfer function is used to evaluate the transducer data and detect impacts.

### Example Processor for Impact Detection

FIG. 9 shows a signal processing module 900 for processing transducer data on a vehicle, according to various embodiments of the disclosure. The signal processing module 900 receives transducer data collected at a data acquisition module, such as the data acquisition module 806 of FIG. 8. In some examples, the signal processing module 900 input is a digital signal. Additionally, the signal processing module 900 receives ISM/CMM (Inertial Sensing Module/Chassis Motion Module) data from an ISM module 914 and odometer data from the vehicle odometer 916. The signal processing module 900 includes a low pass filter 902, a coherence calculation module 904, a noise filter 906, a summing module 908, and a detector 910. Additionally, the signal processing module 900 includes a diagnostics module 912, which received odometer 916 data and calculates a gravity vector when the vehicle is stationary. In some examples, the diagnostics module 912 performs a root mean squared (RMS) calculation.

The digital signal input to the signal processing module 900 is filtered at the filter 902. In some implementations, the filter 902 is a low pass filter. In some examples, the low pass filter filters out frequencies above about 800 Hz. In some examples, the low pass filter filters out frequencies above about 500 Hz. In some implementations, the filter 902 is a band pass filter. In some examples, the band pass filter filters out frequencies around that of the vehicle suspension. In some examples, the band pass filter filters out frequencies around 2 kHz. The filtered signal from the filter is then input to the coherence calculation module 904, which performs a coherence calculation to remove chassis-driven motion from the signal. The coherence calculation module 904 also receives ISM/CMM input data.

In some examples, coherence equations are used to split the transducer data spectrum into categories. In particular, coherence equations can be used to split the transducer data spectrum into a portion that includes chassis-driven data and a portion that includes wind or other noise-driven data. The output from the coherence calculation module 904 is input to a noise filter 906 which also receives odometer data from the odometer 916, and removes noise such as wind noise and/or road noise from the signal.

The processed signal from the noise filter 906 is input to the processing summing module 908, which performs a Pythagorean sum for each tri-axis. In some examples, the Pythagorean sum includes total energy across all axes. In some examples, the Pythagorean sum includes energy that is normal to the surface of the vehicle, since the energy normal to the surface is generally more likely to be caused by an impact rather than wind noise, road noise, a speed bump, and/or other types of noise. The output from the summing module 908 is input to a detector 910, which performs threshold-based detection. In particular, the detector 910 determines whether the input exceeds one or more selected thresholds and indicates a vehicle impact. The detector 910 output is the signal processing module 900 output, and is input to an impact detection module, such as the impact detection module 814 of FIG. 8.

### Example Impact Detection Module

FIG. 10 shows impact detection module 1000 for detecting impacts to a vehicle, according to various embodiments of the disclosure. The impact detection module 1000 receives transducer data collected at a data acquisition module, such as the data acquisition module 806 of FIG. 8. Additionally, the impact detection module 1000 receives data from an inertial measurement unit. In some examples, the inertial measurement unit is an accelerometer positioned on a center of mass of the rigid body of the vehicle. In some examples, the impact detection module 1000 also receives input from various other vehicle sensors, including, for example, LiDAR data, camera data, radar data, ultrasonics data, odometer data, and ISM/CMM data.

The impact detection module 1000 uses a filter 1006 to process the received data. The filter 1006 uses a sensor fusion algorithm to fuse multiple inputs. In particular, the input is used to compute a set of features 1002. The features derived from vehicle sensor data are characterized with respect to the likelihood of a collision given the particular value of the feature. In some implementations, the features 1002 are input to a set of likelihood curve modules 1004. In some examples, the likelihood curve modules determine the likelihood of a collision according to the current trajectory of the data. In some examples, for one or more features, the likelihood calculation is based on an assumption that no action is taken and no deviation occurs from the current trajectory. The data from the likelihood curve modules 1004 is combined at the filter 1006. In one example, the filter 1006 includes a binary bayes fusion model adapted for multiple features. The filter 1006 generates a confidence that a collision is currently occurring. In some examples, a threshold is placed at a specific confidence to delineate collisions from non-collisions. The filter 1006 output is input to a control module 1008, which interprets the filter 1006 output and determines whether to activate a downstream collision response protocol 1010.

### Example Method for Impact Detection

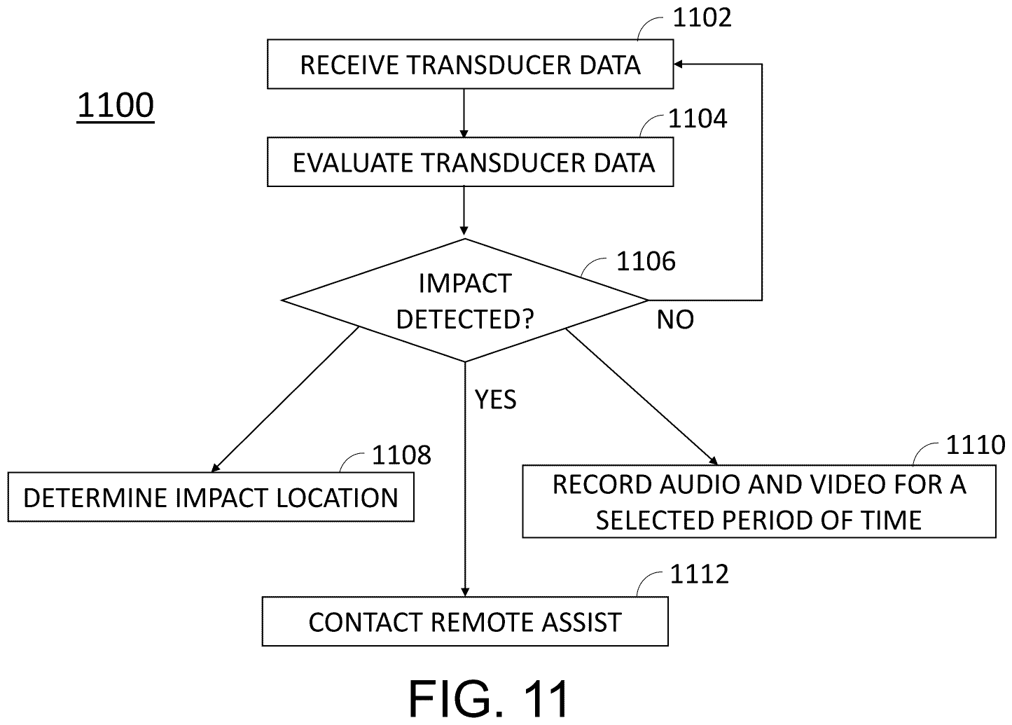

FIG. 11 shows a method 1100 for monitoring the detecting impacts to a vehicle, according to various embodiments of the disclosure. At step 1102, transducer data is received at a bus. The transducer data is analog data and it can be converted to a digital signal at an analog-to-digital converter on the bus. A transceiver can be used to transmit the transducer data to a data acquisition module. In various examples, the data acquisition module receives data from multiple transducers. The data acquisition module combines the transducer data from multiple transducers and, in some examples, performs filtering functions on the transducer data. In some examples, the data acquisition module pre-processes the transducer data. In some examples, the data acquisition module filters out transducer data deviations caused by vandalism. In other examples, the data acquisition module filters out transducer data deviations caused by the vehicle being towed.

The data acquisition module transmits the transducer data to a computing system, such as the onboard computer 104 in the autonomous vehicle of FIG. 1. The computing system includes a processor, and, at step 1104, the processor processes the transducer data. In various examples, the processor also receives data from a sensor suite, such as the sensor suite 102 of FIG. 1. The processor includes a signal processing module and an impact detection module. The signal processing module filters the transducer data, reducing noise in the data, such as wind noise, road noise and chassis noise. The processor also receives odometer data from a main inertial sensor which can contribute to information about expected wind noise. The impact detection module receives the transducer data and the filtered data from the signal processing module and determines whether a collision occurred. In some examples, the impact detection module determines the likelihood that a collision has occurred. In some examples, the impact detection module determines the likelihood that a collision will occur.

At step 1106, the processor determines if an impact is detected. In some examples, the new transducer data is compared to typical transducer data to detect outliers and/or deviations. In some examples, the new transducer data is compared to previous transducer data to detect outliers and/or deviations. If no impact is detected at step 1106, the method returns to step 1102. In some examples, the transducers are permanently installed in the vehicle, and transducer data is regularly evaluated. In some implementations, transducer data is collected to identify transducer data patterns.

If, at step 1106, an impact is detected, the onboard computer initiates an impact detection protocol. The impact detection protocol includes, at step 1108, determining the location of the impact. In some examples, the location of the impact is determined based data from each of a plurality of transducers and a lookup table that indicates expected transducer data for each of the transducers based on an impact at a specified location. The impact detection protocol further includes, at step 1110, recording (and saving) audio and video for a selected period of time surrounding the impact. In some examples, audio and video recordings for a selected period of time before and after the impact are saved. In various examples, the selected period of time is 30 seconds, one minute, or more than one minute. The impact detection protocol further includes, at step 1112, contacting remote assist. Remote assist includes a human operator who can evaluate sensor data from the vehicle, including audio and video data, and determine the type of impact event and the severity of the impact event.

In some examples, the human operator can contact emergency services. In some examples, following a detected impact, the vehicle is routed to a service center for evaluation of damage caused by the impact and, potentially, for repair of any damage. In some examples, following a detected impact, the vehicle is towed to a service center for repair.

As described herein, one aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

### SELECT EXAMPLES

Example 1 provides a method for simulating a sensor signal which has measured a collision with an object comprises retrieving a waveform from a lookup table, scaling the waveform by a first scaling factor, retrieving a predetermined road noise waveform, and combining the road noise waveform with the waveform scaled by the first scaling factor.

Example 2 provides a system according to any one of the preceding or proceeding systems and/or methods, wherein the waveform is based at least on a material of the object.

Example 3 provides a system according to any one of the preceding or proceeding systems and/or methods, the waveform is based at least on a contact area of the object.

Example 4 provides a system according to any one of the preceding or proceeding systems and/or methods, the first scaling factor is based at least on an inertia of the object.

Example 5 provides a system according to any one of the preceding or proceeding systems and/or methods, the first scaling factor is based at least on an angle of incidence of the object.

Example 6 provides a system according to any one of the preceding or proceeding systems and/or methods, further comprising scaling the waveform by a second scaling factor.

Example 7 provides a system according to any one of the preceding or proceeding systems and/or methods, the second scaling factor is based at least on geometric spreading between the object collision and sensor.

Example 8 provides a system according to any one of the preceding or proceeding systems and/or methods, the second scaling factor is based at least on acoustic attenuation between the object collision and sensor.

Example 9 provides a system according to any one of the preceding or proceeding systems and/or methods, the second scaling factor is a transfer function.

Example 10 provides a system according to any one of the preceding or proceeding systems and/or methods, the transfer function is in the frequency domain.

Example 11 provides a system according to any one of the preceding or proceeding systems and/or methods, further comprising introducing a temporal delay in the scaled waveform.

Example 12 provides a system according to any one of the preceding or proceeding systems and/or methods, the temporal delay is based at least on a distance between the object collision and sensor.

Example 13 provides a system according to any one of the preceding or proceeding systems and/or methods, the road noise waveform based on at least one of a vehicle's speed and road quality.

Example 14 provides a system according to any one of the preceding or proceeding systems and/or methods, further comprising combining the scaled signal with the road noise waveform.

Example 15 provides a system for twelve-octave simulating a collision sensor signal comprises a first database for retrieving a waveform from a lookup table, a circuit configured to scale the waveform by a first scaling factor, a second database for retrieving a predetermined road noise waveform, and a circuit configure to combine the road noise waveform with the waveform scaled by the first scaling factor, wherein the road noise waveform is based on at least one of a vehicle's speed and road quality.

Example 16 provides a system according to any one of the preceding or proceeding systems and/or methods, the waveform is based on at least one of a material of the object and contact area of the object.

Example 17 provides a system according to any one of the preceding or proceeding systems and/or methods, the first scaling factor is based on at least one of inertia of the object and angle of incidence.

Example 18 provides a system according to any one of the preceding or proceeding systems and/or methods, further comprising a circuit configured to scale the waveform by a second scaling factor, the second scaling factor based on at least one of geometric spreading between the object collision and sensor and acoustic attenuation between the object collision and sensor.

Example 19 provides a system according to any one of the preceding or proceeding systems and/or methods, further comprising a time delay circuit.

Example 20 provides a method for detecting a collision in an autonomous vehicle comprises modelling a touch and collision transducer surface as a collision projection spline, the collision projection spline being a theoretical circle which partially overlaps with the autonomous vehicle, receiving touch and collision transducer signals from an array of sensors disposed on the autonomous vehicle, detecting an overlap in a collision event and surface of the autonomous vehicle, and calculating a spline distance between the collision event and closet sensor in the sensor array.

### Variations and Implementations

As will be appreciated by one skilled in the art, aspects of the present disclosure, in particular aspects of a perception system for an autonomous vehicle, described herein, may be embodied in various manners (e.g., as a method, a system, a computer program product, or a computer-readable storage medium). Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module,” or “system.” Functions described in this disclosure may be implemented as an algorithm executed by one or more hardware processing units, e.g. one or more microprocessors, of one or more computers. In various embodiments, different steps and portions of the steps of each of the methods described herein may be performed by different processing units. Furthermore, aspects of the present disclosure may take the form of a computer program product embodied in one or more computer-readable medium(s), preferably non-transitory, having computer-readable program code embodied, e.g., stored, thereon. In various embodiments, such a computer program may, for example, be downloaded (updated) to the existing devices and systems (e.g. to the existing perception system devices and/or their controllers, etc.) or be stored upon manufacturing of these devices and systems.

The following detailed description presents various descriptions of specific certain embodiments. However, the innovations described herein can be embodied in a multitude of different ways, for example, as defined and covered by the claims and/or select examples. In the following description, reference is made to the drawings where like reference numerals can indicate identical or functionally similar elements. It will be understood that elements illustrated in the drawings are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The preceding disclosure describes various illustrative embodiments and examples for implementing the features and functionality of the present disclosure. While particular components, arrangements, and/or features are described below in connection with various example embodiments, these are merely examples used to simplify the present disclosure and are not intended to be limiting. It will of course be appreciated that in the development of any actual embodiment, numerous implementation-specific decisions must be made to achieve the developer's specific goals, including compliance with system, business, and/or legal constraints, which may vary from one implementation to another. Moreover, it will be appreciated that, while such a development effort might be complex and time-consuming; it would nevertheless be a routine undertaking for those of ordinary skill in the art having the benefit of this disclosure.

In the Specification, reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as “above”, “below”, “upper”, “lower”, “top”, “bottom”, or other similar terms to describe a spatial relationship between various components or to describe the spatial orientation of aspects of such components, should be understood to describe a relative relationship between the components or a spatial orientation of aspects of such components, respectively, as the components described herein may be oriented in any desired direction. When used to describe a range of dimensions or other characteristics (e.g., time, pressure, temperature, length, width, etc.) of an element, operations, and/or conditions, the phrase “between X and Y” represents a range that includes X and Y.

Other features and advantages of the disclosure will be apparent from the description and the claims. Note that all optional features of the apparatus described above may also be implemented with respect to the method or process described herein and specifics in the examples may be used anywhere in one or more embodiments.

The ‘means for’ in these instances (above) can include (but is not limited to) using any suitable component discussed herein, along with any suitable software, circuitry, hub, computer code, logic, algorithms, hardware, controller, interface, link, bus, communication pathway, etc. In a second example, the system includes memory that further comprises machine-readable instructions that when executed cause the system to perform any of the activities discussed above.

What is claimed is:

1. A method for simulating a sensor signal which has measured a collision with an object comprising:
retrieving a waveform from a memory location;
scaling the waveform by a first scaling factor;
retrieving a predetermined road noise waveform; and
combining the road noise waveform with the waveform scaled by the first scaling factor.

2. The method according to claim 1, wherein the waveform is based at least on a material of the object.

3. The method according to claim 1, wherein the waveform is based at least on a contact area of the object.

4. The method according to claim 1, wherein the first scaling factor is based at least on an inertia of the object.

5. The method according to claim 1, wherein the first scaling factor is based at least on an angle of incidence of the object.

6. The method according to claim 1 further comprising scaling the waveform by a second scaling factor.

7. The method according to claim 6, wherein the second scaling factor is based at least on geometric spreading between the object collision and sensor.

8. The method according to claim 6, wherein the second scaling factor is based at least on acoustic attenuation between the object collision and sensor.

9. The method according to claim 6, wherein the second scaling factor is a transfer function.

10. The method according to claim 9, wherein transfer function is in the frequency domain.

11. The method according to claim 1 further comprising introducing a temporal delay in the scaled waveform.

12. The method according to claim 11, wherein the temporal delay is based at least on a distance between the object collision and sensor.

13. The method according to claim 1, wherein the road noise waveform is based on at least one of a vehicle's speed and road quality.

14. The method according to claim 13 further comprising combining the scaled signal with the road noise waveform.

15. A system for simulating a collision sensor signal comprising:
a first database to store a waveform;
a circuit to retrieve and scale the waveform by a first scaling factor;
a second database to store a predetermined road noise waveform; and
a circuit to retrieve the road noise waveform, and combine the road noise waveform with the waveform scaled by the first scaling factor;
wherein the road noise waveform is based on at least one of a vehicle's speed and road quality.

16. The system according to claim 15, wherein the waveform is based on at least one of a material of an object and contact area of the object.

17. The system according to claim 15, wherein the first scaling factor is based on at least one of inertia of an object and angle of incidence.

18. The system according to claim 15 further comprising a circuit configured to scale the waveform by a second scaling factor, the second scaling factor based on at least one of geometric spreading between an object collision and sensor and acoustic attenuation between the object collision and sensor.

19. The system according to claim 15 further comprising a time delay circuit.

20. A method for detecting a collision in a vehicle comprising:
retrieving a model of a touch and collision transducer surface as a collision projection spline, the collision projection spline being a theoretical circle which partially overlaps with the vehicle;
receiving touch and collision transducer signals from an array of sensors disposed on the vehicle;
detecting an overlap in a collision event and surface of the vehicle based at least on the received touch and collision transducer signals and retrieved model; and
calculating a spline distance between the collision event and closest sensor in the sensor array based on the collision projection spline.
